(19) United States
(12) Patent Application Publication
(10) Pub. No.: US 2021/0268650 A1
(43) Pub. Date: Sep. 2, 2021

(54) CONTROL DEVICE AND CONTROL METHOD

(71) Applicant: Sony Corporation, Tokyo (JP)

(72) Inventor: Hirotaka Suzuki, Kanagawa (JP)

(73) Assignee: Sony Corporation, Tokyo (JP)

(21) Appl. No.: 17/254,210

(22) PCT Filed: May 7, 2019
(86) PCT No.: PCT/JP2019/018281

§ 371 Date: Dec. 18, 2020

(30) Foreign Application Priority Data
Jun. 29, 2018 (JP) 2018-125031

(51) Int. Cl. B25J 9/16; G05D 1/02

(52) U.S. Cl. CPC B25J 9/1653; G05D 1/0217; B25J 9/1694; B25J 9/1664; G05D 1/0219

(57) ABSTRACT

A control device (1b) according to an embodiment includes a control unit (11), an estimating unit (100), and a correcting unit (103). The control unit included in the control device performs a control based on first chronological information, of an action of a controlled object (3). The estimating unit included in the control device performs estimation of a cost produced by achievement of a purpose of the controlled object. The correcting unit included in the control device performs correction of an action based on the first chronological information of the controlled object according to the cost estimated by the estimating unit.

### FIELD

The present invention relates to a control device and a control method.

### BACKGROUND

By reproducing a log that has been recorded with an action of an action target object, it is possible to cause the action target object to re-act. Such a re-action by reproduction of the log is often used for a limited context. For example, when a log same as left of the action target object is to be recorded, measures of isolating the action target object from others to avoid interference from the other objects, preventing the other objects from being within a movable range of the action target object, and the like are taken.

### CITATION LIST

### Patent Literature

Patent Literature 1: Japanese Patent No. 4163624
Patent Literature 2: International Publication Pamphlet No. WO 2017/163538
Non Patent Literature 1: Mariusz Bojarski, and 12 others, “End to End Learning for Self-Driving Cars”, [online], Apr. 25, 2016, [retrieved on Apr. 25, 2018], the Internet <https://images.nvidia.com/content/tegra/automotive/images/2016/solutions/pdf/end-to-end-dl-using-px.pdf>

### SUMMARY

### Technical Problem

The re-action according to a log can cause an unexpected action in an environment other than the limited context according to the log, and is susceptible to improvement.

The present disclosure proposes a control device and a control method that are capable of more appropriately controlling an action according to a log.

### Solution to Problem

For solving the problem described above, a control device according to one aspect of the present disclosure has a control unit that controls an action of a controlled object based on first chronological information; an estimating unit that estimates a cost produced by achievement of a purpose of the controlled object; and a correcting unit that corrects an action of the controlled object based on the first chronological information, according to the cost estimated by the estimating unit.

### Advantageous Effects of Invention

According to the present disclosure, an action according to a log can be more appropriately controlled. Effects described herein are not necessarily limited, but any effect described in the present disclosure may be produced.

### BRIEF DESCRIPTION OF DRAWINGS

FIG. 1 is a diagram illustrating a basic configuration of a control system that controls an action of a controlled object based on log information.

FIG. 2 is a diagram illustrating an example of a configuration of the control system that is applicable to respective embodiments of the present disclosure.

FIG. 3 is a block diagram illustrating an example of a hardware configuration of a controlled object applicable to an embodiment.

FIG. 4 is a block diagram illustrating an example of a hardware configuration of the control device applicable to an embodiment.

FIG. 5 is an example of a functional block diagram for explaining a function of an action correcting unit according to a first embodiment.

FIG. 6 is an example of a flowchart illustrating control processing of a controlled object according to the first embodiment.

FIG. 7 is an example of a flowchart illustrating action correction processing according to the first embodiment.

FIG. 8 is a diagram illustrating an example of log information recorded in a log recording unit applicable to the first embodiment.

FIG. 9 is a diagram illustrating an example of the log information recorded in the log recording unit applicable to the first embodiment.

FIG. 10 is a diagram for explaining necessity of smoothing processing.

FIG. 11 is a diagram for explaining smoothing processing applicable to the first embodiment.

FIG. 12 is a diagram for explaining read-ahead processing applicable to the first embodiment.

FIG. 13 is an example of a functional block diagram for explaining a function of an action correcting unit according to a second embodiment.

FIG. 14 is an example of a flowchart illustrating action correction processing according to the second embodiment.

FIG. 15 is an example of a functional block diagram for explaining a function of an action correcting unit according to a third embodiment.

FIG. 16 is an example of a flowchart illustrating action correction processing according to the third embodiment.

### DESCRIPTION OF EMBODIMENTS

Hereinafter, embodiments of the present disclosure will be explained in detail with reference to the drawings. In the following embodiments, like reference symbols are assigned to like parts, and duplicated explanation will be thereby omitted.

[Overview of Present Disclosure]

A control device according to the present disclosure is configured to estimate a cost produced as a purpose is achieved by an action of a controlled object, the action of which is controlled based on log information, and to correct the action based on the log information of the controlled object according to the estimated cost. Therefore, according to the control device according to the present disclosure, the action of the controlled object based on the log information can be controlled more appropriately.

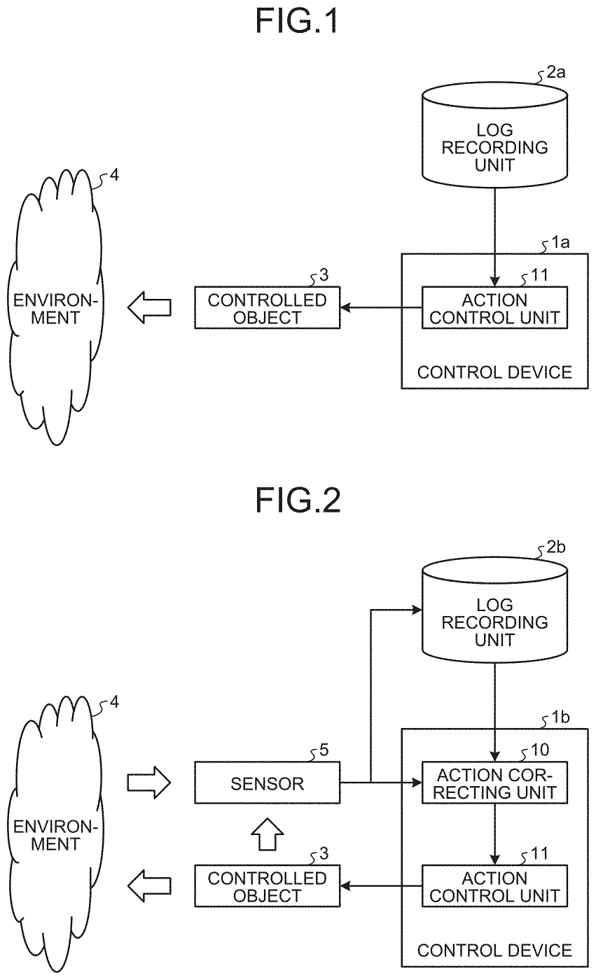

Before explanation of the present disclosure, a basic configuration to control an action of a controlled object based on log information will be explained to facilitate understanding. FIG. 1 is a diagram illustrating a basic configuration of a control system that controls an action of a controlled object based on log information. In FIG. 1, the control system includes a control device 1a and a log recording unit 2a. Moreover, the control device 1a includes an action control unit 11, and controls an action of a controlled object 3 in an environment 4.

The log recording unit 2a stores data of a motion wished to be made by the controlled object 3 in advance as log information. This log information includes, for example, control data per unit time corresponding to an action of the controlled object 3, and is chronological information that expresses an action of the controlled object 3 chronologically. In the control device 1a, the action control unit 11 controls the action of the controlled object based on the log information acquired from the log recording unit 2a. More specifically, the action control unit 11 generates a control signal for the controlled object 3 to transition from a current state to a next state, and outputs it. The controlled object 3 operates in the environment 4 according to this control signal.

For explanation, it is assumed that the controlled object 3 is a robot, an action of which is controlled according to a control signal. It is assumed as a premise that other objects, for example, other robots and people coexist and cooperate in the environment in which the controlled object 3 that operates based on the log information is caused to actually operate.

Collection of the log information according to an action of the controlled object 3 is performed in an environment in which these other objects are completely removed. Not limited thereto, collection of the log information of the controlled target 3 can be performed in an environment in which coexistence of the other objects are allowed. In either case of collecting of the log information in either of the environments, most of the time, a state at the time of collection differs from a state in which the controlled object 3 is actuated for an actual purpose. Therefore, there is a possibility that the controlled object 3 causes an interference and collision with other objects if the controlled object 3 is operated simply according to the log information.

As one example of the controlled object 3, an arm robot that performs parts assembly work by using a movable arm is considered. In this case, it is common that a parts assembly work is programmed into the robot arm by using a teaching pendant or the like, and that the arm robot is operated according to the program in a replay motion, to perform the assembly work. In this case, if it is not in a state in which the arm robot is in complete isolation, collision with another object can occur. In a work environment with multiple units of robot in small space, or when a cooperative work is performed in a coexisting situation with a human and another robot, the collision problem cannot be avoided.

FIG. 2 is a diagram illustrating an example of a configuration of the control system that is applicable to respective embodiments of the present disclosure. In the control system illustrated in FIG. 2, a sensor 5 is additionally provided, and an action correcting unit 10 is provided in a control device 1b, additionally to the control device 1a illustrated in in FIG. 1.

The sensor 5 includes a detecting means that detects a state inside the controlled object 3, and a detecting means that detects a state outside the controlled object 3 in the environment 4. The detecting means that detects a state inside the controlled object 3 includes an angle sensor that acquires an angle of each joint, an action sensor that sequentially detects an action of the controlled object 3, and the like when the controlled object 3 is the arm robot described above. Moreover, the detecting means that detects a state outside the controlled object 3 includes a camera to image a periphery of the controlled object 3, or a periphery of the controlled object 3 including the controlled object 3 itself. As the detecting means that detects an external state, a depth sensor that measures a distance, and a temperature sensor that measures temperature may be further added.

In a log recording unit 2b, log information according to an action of the controlled object 3 is recorded in advance. When the controlled object 3 is a robot for factory automation, such as the arm robot described above, log information based on typical patterns is generated in advance, and is recorded in the log recording unit 2b. Furthermore, the log recording unit 2b can record log information generated according to an action of the controlled object 3 additionally. For example, the log recording unit 2b can record respective information detected by the sensor 5 sequentially.

The action correcting unit 10 included in the control device 1a corrects an action of the controlled object 3 that is controlled by the action control unit 11. The action correcting unit 10 can correct an action of the controlled object 3 based on the log information stored in the log storage unit 2b and an output of the sensor 5. Moreover, the action correcting unit 10 can be configured to perform correction of an action of the controlled object 3 by using a training result trained based on the log information stored in the log storage unit 2b and the like. Furthermore, the action correcting unit 10 can be configured to perform correction of an action of the controlled object 3 based on a user operation.

In FIG. 2, the control device 1b and the log recording unit 2b can be configured to be included in the controlled object 3. Not limited thereto, the control device 1b, the log recording unit 2b, and the controlled object 3 may be configured separately, and the control device 1b and the controlled object 3 may be connected through a predetermined connecting wire. Furthermore, the log recording unit 2b may be connected to the control device 1b through a network, such as a local area network (LAN) and the Internet. In this case, the log recording unit 2b can be connected to plural units of the control device 1b.

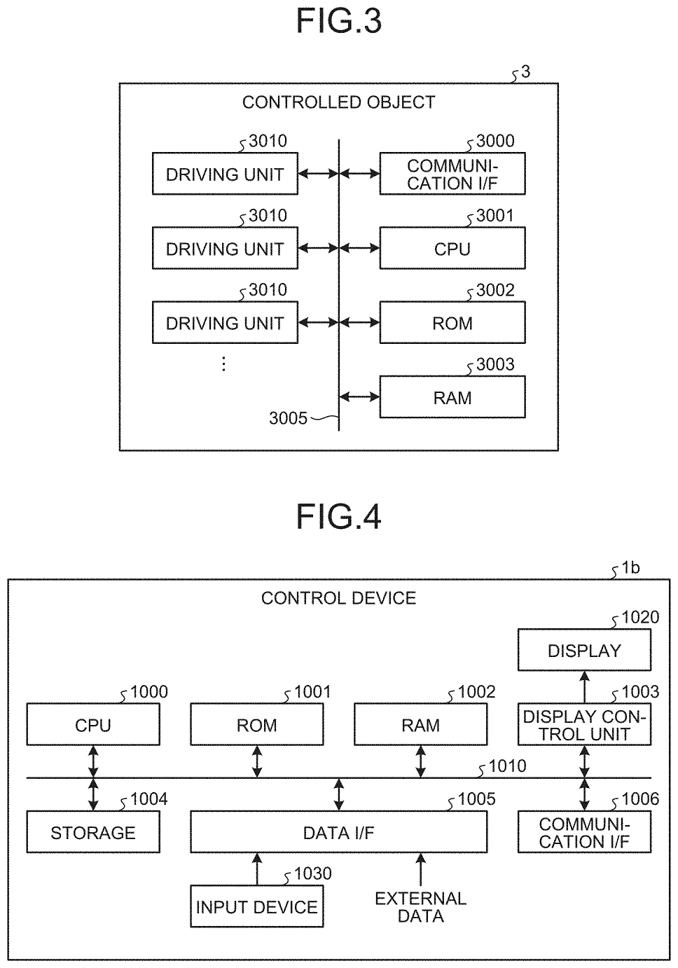

FIG. 3 is a block diagram illustrating an example of a hardware configuration of the controlled object 3 applicable to an embodiment. It is explained herein assuming that the controlled object 3 is a robot such as the arm robot described above.

In the example in FIG. 3, the controlled object 3 includes a communication I/F 3000, a CPU 3001, a ROM 3002, a RAM 3003, and at least one driving unit 3010 that are connected to each other thorough a bus 3005. The communication I/F 3000 is an interface to perform communication with the control device 1b. The respective driving units 3010, 3010, . . . drive respective actuators that actuate a movable portion, such as a joint, for example, included in the controlled object 3, following an instruction from the CPU 3001. The CPU 3001 controls an overall action of the controlled object 3, according to the program stored in the ROM 3002 in advance, and using the RAM 3003 as a work memory. For example, the CPU 3001 gives a drive instruction of the actuator to the respective driving units 3010, 3010, . . . , according to a control signal provided from the control device 1b through the communication I/F 3000. As the respective driving units 3010, 3010, . . . actuate the actuator following a drive instruction, the controlled object 3 operates in accordance with a control instruction from the control device 1b.

Moreover, the respective driving units 3010, 3010, . . . can acquire information indicating an operating state of the corresponding actuators. The acquired information is transmitted to the control device 1b through the communication I/F 3000 by, for example, the CPU 3001.

FIG. 4 is a block diagram illustrating an example of a hardware configuration of the control device 1b applicable to an embodiment. The control device 1b includes a CPU 1000, a ROM 1001, a RAM 1002, a display control unit 1003, a storage 1004, a data I/F 1005, and a communication I/F 1006 that are connected to a bus 1010. Thus, the control device 1b can be implemented by a configuration equivalent to a general computer.

The storage 1004 is a non-volatile storage medium, such as a hard disk drive and a flash memory. The CPU 1000 controls an overall action of this control device 1b according to a program stored in the storage 1004 or the ROM 1001 in advance, using the RAM 1002 as a work memory.

The display control unit 1003 converts a display control signal generated by the CPU 1000 according to the program into a display signal that can be displayed by a display 1020, and outputs it. The display 1020 displays a screen according to the display signal by using the display 1020, for example, a liquid crystal display (LCD), as a display device.

The data I/F 1005 is an interface to perform input and output of data with an external device. As the data I/F 1005, for example, a universal serial bus (USB) can be adopted. Moreover, the data I/F 1005 can connect an input device 1030 that receives a user input, as an external device. The input device 1030 is, for example, a pointing device, such as a mouse and a tablet, and a keyboard. Not limited thereto, a joystick or a gamepad can be adopted as the input device 1030.

In the above description, the controlled object 3 has been explained as an arm robot, but it is not limited to this example. For example, the controlled object 3 may be, for example, an unmanned aerial vehicle (drone) that can be externally flight-controlled. In this case, the respective driving units 3010, 3010, . . . drive motors to rotate, for example, propellers. Moreover, for example, the controlled object 3 may be a moving robot that is structured to be movable, including a moving means, such as two legs, multi-legs, caterpillars, and wheels. In this case, the respective driving units 3010, 3010, . . . drive the actuators to move the joints, and also drive the moving means.

Furthermore, the controlled object 3 may be a virtual device in virtual space, such as a computer game. In this case, the controlled object 3 corresponds to a vehicle in a car race game, a robot in a robot fight game, an athlete in a fighting game or a sport game, or the like. The controlled object 3 in this case is to be a device in virtual space formed by executing a program by the CPU 1000 in the control device 1b. In this case, the sensor 5 can be configured by a program that operates on the CPU 1000 to obtain movements of the controlled object 3 in the virtual space.

### First Embodiment

Next, a first embodiment will be explained. In the first embodiment, the action correcting unit 10 included in the control device 1b performs correction of an action of the controlled object 3 that is controlled by the action control unit 10 by using the log information stored in the log recording unit 2b.

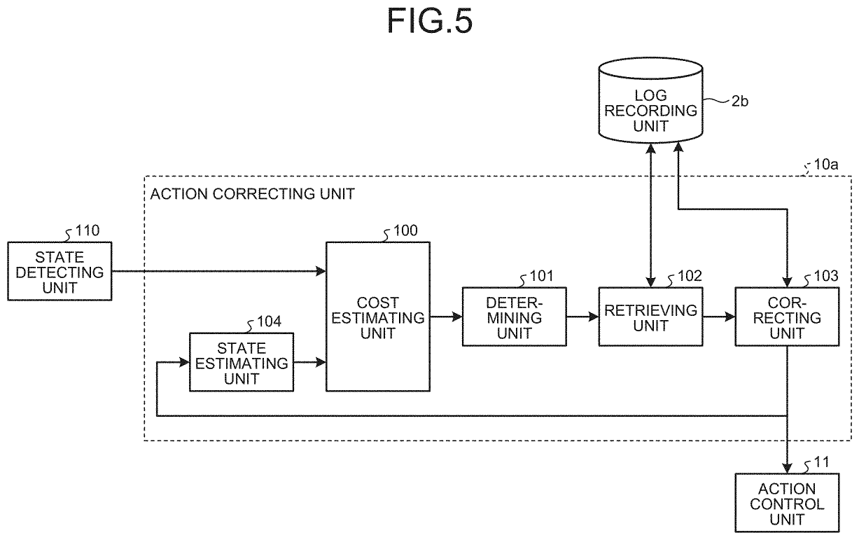

FIG. 5 is an example of a functional block diagram for explaining a function of an action correcting unit 10a according to the first embodiment. In FIG. 5, the action correcting unit 10a includes a cost estimating unit 100, a determining unit 101, a retrieving unit 102, a correcting unit 103, and a state estimating unit 104.

These cost estimating unit 100, determining unit 101, retrieving unit 102, correcting unit 103, and state estimating unit 104 are configured by a program being executed on the CPU 1000. Not limited thereto, some of or all of these cost estimating unit 100, determining unit 101, retrieving unit 102, correcting unit 103, and state estimating unit 104 may be configured by hardware circuits that operate in cooperation with each other.

The program to implement the respective functions according to the first embodiment in the control device 1a is recorded in a computer-readable recording medium, such as a flexible disk (FD) and a digital versatile disk (DVD), in a file in an installable format or an executable format, to be provided. Not limited thereto, the program may be stored in a computer connected to a network, such as the Internet, to be provided by being downloaded through the network. Moreover, the program may be configured to be provided or distributed through a network, such as the Internet.

The program has a module structure including the cost estimating unit 100, the determining unit 101, the retrieving unit 102, the correcting unit 103, and the state estimating unit 104. The action control unit 11 may be further included in this module. As actual hardware, by reading and executing the program from the storage medium, such as the ROM 1001 and the storage 1004, by the CPU 1000, the respective units described above are loaded on a main storage device, such as the RAM 1002, and the cost estimating unit 100, the determining unit 101, the retrieving unit 102, the correcting unit 103, and the state estimating unit 104 are generated on the main storage device.

In FIG. 5, a state detecting unit 110 detects and recognizes a state of the controlled object 3 based on an output of the sensor 5. The state of the controlled object 3 detected by the state detecting unit 110 can include an internal state, an external apparent state of the controlled object 3, and a state of the environment 4 for the controlled object 3 that can be detected by the sensor 5. Hereinafter, unless otherwise specified, combining the internal state and the external apparent state of the controlled object 3 and the state of the environment 4 for the controlled object 3 that are detected based on an output of the sensor 5 will be combined to be explained as a state of the controlled object 3.

The cost estimating unit 100 estimates a cost for achievement of a purpose of an action of the controlled object 3 based on the state of the controlled object 3 that is acquired from the state detecting unit 110 or the state estimating unit 104 described later. For example, when the controlled object 3 performs an action according to the log information recorded in the log recording unit 2b, the cost estimating unit 100 uses a cost function with which a higher cost is calculated as an interference to another object increases, when the purpose is to achieve the action without causing interference (collision, contact) with respect to another object (another device or human).

The determining unit 101 determines whether the cost calculated by the cost estimating unit 100 is equal to or higher than a predetermined value. The retrieving unit 102 retrieves, based on a state of the controlled object 3 detected by the state detecting unit 110, or a state of the controlled object 3 estimated by the state estimating unit 104, for a state similar (similar state) to the detected or estimated state from among states indicated in the log information recorded in the log recording unit 2b. The correcting unit 103 corrects an action based on the log information recorded in the log recording unit 2b, based on the similar state retrieved by the retrieving unit 102, and sends control information indicating a corrected action to the action control unit 11.

When the determining unit determines that the cost is lower than the predetermined value, it is controlled such that the retrieve processing by the retrieving unit 102 and the correction processing by the correcting unit 103 are not performed. In this case, the log information recorded in the log recording unit 2b is to be sent to the action control unit 11, skipping the processing by the correcting unit 103.

When the action based on the log information is corrected by the correcting unit 103, the state estimating unit 104 estimates a state of the controlled object 3 based on the corrected action.

The log information recorded in the log recording unit 2b will be schematically explained. The log recording unit 2b generates log information based on a state of the controlled object 3 detected by, for example, the sensor 5, and records and stores the generated log information. Generation and recording of the log information are continuously performed per step, which is a time unit at the time of controlling the controlled object 3 by the control device 1b, for example. That is, the log information is chronological information in which states of the controlled object 3 are chronologically recorded.

As one example, when the controlled object 3 is a device, such as a robot in virtual space, 1 step is a 1 frame time of 20 frames per second (fps). As another example, when the controlled object 3 is a vehicle in virtual space, 1 step is a 1 frame time of 60 fps. Time length of 1 step is not limited to this example.

The log recording unit 2b records angle information and action information of respective joints that is an internal state of the controlled object 3, image data that is an external state of the controlled object 3, distance information, temperature information, and the like detected by the sensor 5 as the log information for each step. As for the image data, image data itself may be recorded, or pass information of the image data may be recorded or feature information extracted from the image data may be recorded.

Moreover, for example, the log recording unit 2b can record respective position information that is obtained by analyzing the image data taken by a camera serving as the sensor 5, and that includes positions of respective objects included in the image data, as the log information. Furthermore, the log recording unit 2b can record a result obtained by performing class labeling of each pixel of the image data, that is, semantic segmentation of associating with a superordinate concept of a specific object, performed with respect to the image data taken by the camera as the log information. This log information is to be, for example, information to which a label is assigned by semantic segmentation with respect to each object included in an image.

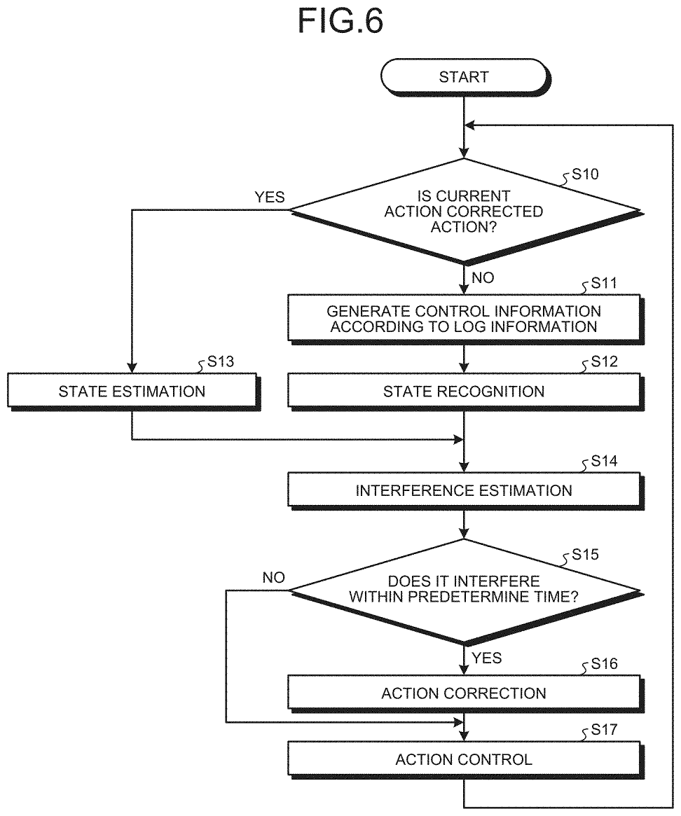

Next, processing according to the first embodiment will be explained in more detail. FIG. 6 is an example of a flowchart illustrating control processing of the controlled object 3 according to the first embodiment. It is supposed that prior to performing the processing according the flowchart in FIG. 6, the control device 1b has generated control information based on the log information recorded in the log recording unit 2b by the action control unit 11, and has been controlling an action of the controlled object 3 with the generated control information.

At step S10, in the control device 1b, the action correcting unit 10a determines whether an action of the controlled object 3 according to the control information generated by the action control unit 11 is an action after subjecting an action based on the log information to correction. When it is determined as not the corrected action (step S10: “NO”), the control device 1b shifts the processing to step S11.

At step S11, the action control unit 11 acquires the log information of a next step from the log recording unit 2, and generates control information based on the acquired log information. The action control unit 11 controls an action of the controlled object 3 based on the generated control information. At following step S12, the action correcting unit 10a recognizes a current state (condition) of the controlled object 3 according to an output of the state detecting unit 110. When the state of the controlled object 3 is recognized, the processing is shifted to step S14.

On the other hand, when it is determined that the action of the controlled object 3 is the corrected action (step S10: “YES”), the action correcting unit 10a shifts the processing to step S13. At step S13, the control device 1b estimates a current state of the controlled object 3 based on the corrected action by the state estimating unit 104. When the state of the controlled object 3 is estimated, the processing is shifted to step S14.

At step S14, the action correcting unit 10a estimates a possibility that the action of the controlled object 3 interferes another object after a predetermined step. The cost estimating unit 100 estimates a possibility of interference after a predetermined step by using an existing method, for example, based on a trajectory of actions of the controlled object 3 and a trajectory of actions of the other object.

For example, when the processing shifts from step S12 described above to this step S14, the trajectory of actions of the controlled object 3 can be acquired based on the log information recorded in the log recording unit 2b. Moreover, when the processing shifts from step S13 to step S14, the trajectory of actions of the controlled object 3 can be acquired by estimation. The trajectory of actions of the other object can be estimated, for example, by analyzing the log information recorded in the log recording unit 2b, tracing back for predetermined steps.

The cost estimating unit 100 calculates this estimated possibility of interference, as an estimated cost for the action of the controlled object 3. At following step S15, the action correcting unit 10a determines, by the determining unit 101, whether there is a possibility that the action of the controlled object 3 interferes the other object within predetermined steps from a current point, based on the calculated cost. For example, the determining unit 101 performs threshold determination with respect to the cost calculated at step S14, and determines that there is a possibility of interference when the cost is equal to or higher than the threshold.

At step S15, when it is determined that there is no possibility of interference (step S15: “NO”), the determining unit 101 shifts the processing to step S17. At step S17, the control device 1b generates, by the action control unit 11, control information based on the log information recorded in the log recording unit 2, and controls the action of the controlled object 3. Thereafter, the processing is returned to step S10.

On the other hand, when it is determined that there is a possibility of interference occurring at some point within predetermined steps from the current point (step S15: “YES”), the determining unit 101 shifts the processing to step S16. At step S16, the action correcting unit 10a corrects, for example, the action based on the log information corresponding to a current time, recorded in the log recording unit 2. For example, the action correcting unit 10a corrects the action so as to avoid the interference, the possibility of which has been estimated at step S14. When the action is corrected, the processing is shifted to step S17. In this case, the action control unit 11 generates, at step S17, control information according to the corrected action, and controls the action of the controlled object 3. Thereafter, the processing is returned to step S10.

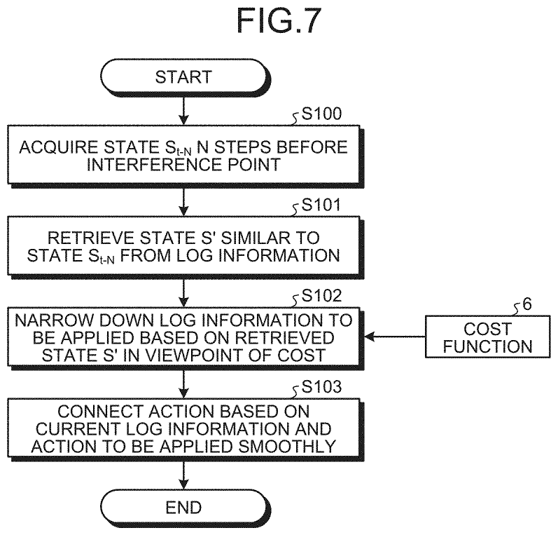

FIG. 7 is an example of a flowchart illustrating action correction processing according to the first embodiment. The processing according to the flowchart in FIG. 7 corresponds to the processing at step S16 in the flowchart in FIG. 6 described above.

At step S100, the action correcting unit 10a acquires, by the retrieving unit 102, a state S_{t-N} at a time N steps before (N is a positive integer) the point of time when the determining unit 101 determines that there is a possibility of interference at step S15 in FIG. 6, based on the log information recorded in the log recording unit 2.

At following step S101, the action correcting unit 10a retrieves, by the retrieving unit 102, a state S′ similar to the state S_{t-N} acquired at step S100 from the log information recorded in the log recording unit 2. The retrieving unit 102 retrieves the log information corresponding to the state S_{t-N} for log information corresponding to the state S′ from past log information. The retrieving unit 102 can output plural pieces of log information corresponding to the state S′ as a retrieve result.

The similar state is a state in which a positional relation of the controlled object 3 with respect to the other object is in a geometrically similar arrangement between two pieces of log information when a barycentric orbit (position) of the controlled object 3 is focused. As an example of the geometrically similar arrangement, a case in which a difference in Euclidean distance is equal to or smaller than a predetermined value is considered. Moreover, as determination of the similarity using image data taken by the camera, determination whether positional relations between a segment of the controlled object 3 and a segment of the other object are similar to each other as a result of performing the semantic segmentation between two pieces of the log information is applied.

The similar state is not limited to this example. For example, the similar state may be a state in which the environment 4 in which the controlled object 3 operates is similar. That is, when the controlled object 3 operates in the plural different environments 4, an environment that is similar to the environment 4 in which the controlled object 3 currently operates is retrieved from the log information acquired in the respective environments 4. As an environment related to a similar state, a brightness, a temperature, a wind, and the like around the controlled object 3 can be considered. Moreover, when the controlled object 3 is a moving object that moves on a road surface, a condition of the road surface (bumps and dips, wet or dry, inclination) and the like can be considered. These environments 4 can be applied to both real space and virtual space.

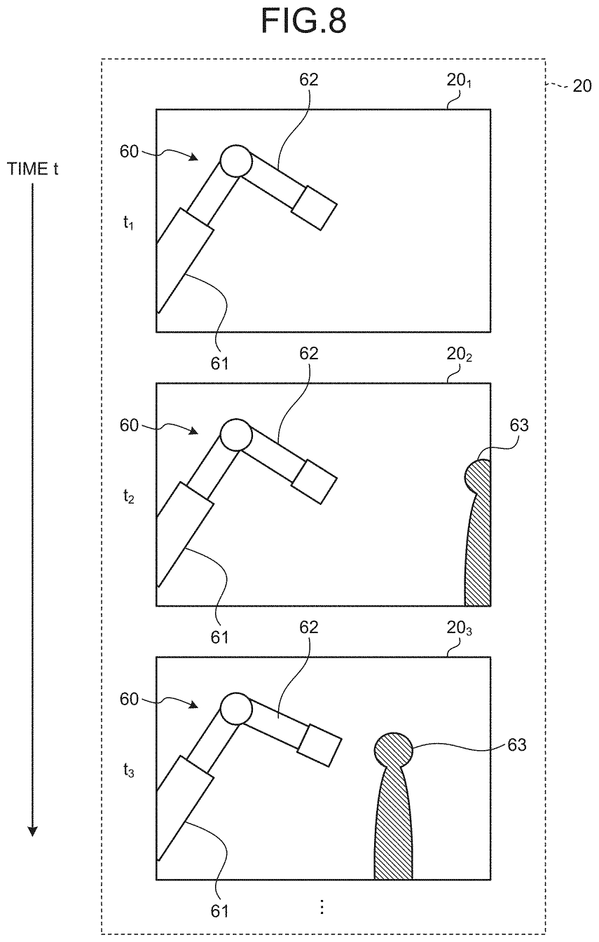

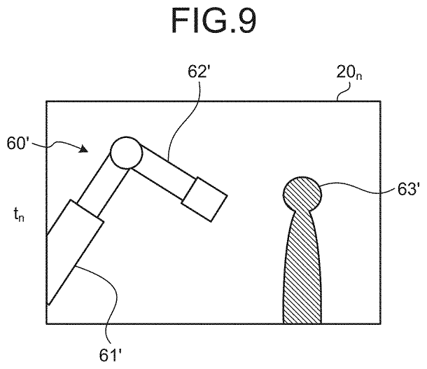

The retrieve processing at step S101 will be explained more specifically by using FIG. 8 and FIG. 9. FIG. 8 and FIG. 9 are diagrams illustrating an example of the log information recorded in the log recording unit 2b applicable to the first embodiment. In the example in FIG. 8 and FIG. 9, log information 20 recorded in the log recording unit 2b is indicated as an image for explanation. For example, the log recording unit 2b records information in which a class label is added to each pixel of image data based on the semantic segmentation performed with respect to the image data included in the log information, in the log information 20. Thus, based on the log information 20, relative positional relation between a position of a segment by the controlled object 3 and a position of a segment by the other object can be acquired. In the example in FIG. 8 and FIG. 9, each segment is indicated as an image of an object to which the segment corresponds.

In FIG. 8, the log information 20 includes log information 20₁, 20₂, 20₃, . . . of respective times t₁, t₂, t₃, . . . by plural steps in chronological order of a time t. In the example in FIG. 8, the log information 20₁ at the time t₁ includes an image of an arm robot 60, which is the controlled object 3. In the example in FIG. 8, the arm robot 60 includes an image of a proximal portion 61 of the arm robot, and an image of an arm portion 62 that is rotatable about a joint portion relative to the proximal portion.

The log information 20₂ at the next time t₂ includes the arm robot 60, and a part of an image of a human 63 as objects. It is found that in the arm robot 60, an angle of the arm portion 62 relative to the proximal portion 61 has not changed from that in the log information 20₁.

The log information 20₃ at the next time t₃ includes the arm robot 60 and the human 63 as objects similarly to the log information 20₂. It is found that in the log information 20₃, the human 63 has moved toward the center relative to that of the log information 20₂. Moreover, it is found that in the log information 20₃, an angle of the arm portion 62 relative to the proximal portion 61 of the arm robot 60 has not changed from that in the log information 20₁ and the log information 20₂ at the earlier time t₁ and time t₂.

FIG. 9 is a diagram illustrating an example of a log information 20n in the state S_{t-N} acquired at step S100. The log information 20n illustrated in FIG. 9 includes an image of an arm robot 60′ having a proximal portion 61′ and an arm portion 62′ and an image of a human 63′ corresponding to the image of the arm robot 60 having the proximal portion 61 and the arm portion 62 and the image of the human 63 included in the log information 20 illustrated in FIG. 8, respectively.

When the respective log information 20₁, 20₂, 20₃, . . . in FIG. 8 and the log information 20n in FIG. 9 are compared, it can be determined that the log information 20₃ has a high degree of similarity to the log information 20n in the state S_{t-N} among the log information 20₁, 20₂, 20₃, . . . based on positional relations between the arm robots 60 and 60′ and between the humans 63 and 63′. Therefore, at step S101, the retrieving unit 102 can determine that the state of the log information 20₃ is the state S′ similar to the state S_{t-N}.

The respective times t₁, t₂, t₃, . . . corresponding to the respective log information 20₁, 20₂, 20₃, . . . in FIG. 8 are past times relative to a time tₙ corresponding to the log information 20n. The time tₙ is a time N steps earlier from a current time, and are past times chronologically continuous to a current action of the controlled object 3.

On the other hand, the respective times t₁, t₂, t₃, . . . in FIG. 8 are not necessary to be chronologically continuous to the current action of the controlled object 3. For example, the time tₙ may be a time when an action is restarted following suspension of the action after the arm robot 60 as the controlled object 3 operates at the respective times t₁, t₂, t₃, . . . chronologically. Moreover, the respective log information 20₁, 20₂, 20₃, . . . in FIG. 8 and the log information 20n in FIG. 9 may be information acquired in different environments. Therefore, a time series including the respective times t₁, t₂, t₃, . . . and a time series including the time tₙ in FIG. 9 can be regarded as different time series.

Returning back to explanation of FIG. 7, when the state S′ is retrieved at step S101, the processing is shifted to step S102. When the state S′ is retrieve in plurality, the retrieving unit 102 narrows down log information to be applied from among respective log information corresponding to the states S′ from the viewpoint of cost at step S102. For example, the retrieving unit 102 defines a cost function 6 to determine whether a resultant action is good, and can select log information, the cost of which calculated according to this cost function 6 is smallest from among the plural pieces of retrieved log information.

For example, when the controlled object 3 is a robot, the cost function 6 with which a cost becomes lower as the possibility that the controlled object 3 causes interference (collision) with the other object decreases is considered. Not limited thereto, a cost function with which a cost becomes lower as an absolute value or a sum of squares of acceleration of the respective actuators is small (that is, when a quick sudden movement is not made) is considered. Moreover, the cost function 6 with which a cost takes a higher value as it becomes closer when a distance of the controlled object 3 from the other object including a static obstacle is equal to or smaller than a predetermined distance is considered. Furthermore, setting the cost function 6 with which a value of cost becomes lower as when an energy consumption decreases can also be considered. Furthermore, time can be an element of the cost. For example, setting a high value to the cost when much time is necessary to perform a specific action (avoidance action and the like) can be considered.

Furthermore, when the controlled object 3 is a virtual device in virtual space, when the controlled object 3 is a virtual device in virtual space, the cost function 6 considering a possibility of collision (interference) and other factors can be set. For example, when the controlled object 3 is a vehicle for car races, setting the cost function 6 in which a speed of at least one of the relevant vehicle and another vehicle having the possibility of interference with the relevant vehicle is considered in priority with respect to the possibility of collision can be considered. As one example, when the collision possibility is 60% or higher, the cost relating to the action for the vehicle to take the avoidance action is to be a low value, and when the collision possibility is lower than 60%, the cost function 6 with which the cost relating to an action to increase the speed of the vehicle to a high speed is to be a low value is considered. As another example, plural kinds of the cost functions 6 with different conditions may be prepared, and a cost function to be applied may be selected from among the plural cost functions 6 randomly, or according to a specific rule.

At step S101, log information corresponding to the state S′ is retrieved from among past log information. Accordingly, a series of actions in predetermined time period (for example, 10 seconds) starting from the state S′ can be acquired for the log information. Therefore, the cost calculation by the cost function 6 is enabled.

Returning back to explanation of FIG. 7, when the log information to be applied is narrowed down at step S102, the processing is shifted to step S103. At step S103, in the action correcting unit 10a, the correcting unit 103 connects the action based on the current log information and the action by the applied log information narrowed down at step S102 are connected, and the action based on the current log information is corrected by the action by the applied log information. At that time, the correcting unit 103 performs smoothing processing to smoothly connect the action based on the current log information and the action by the applied log information.

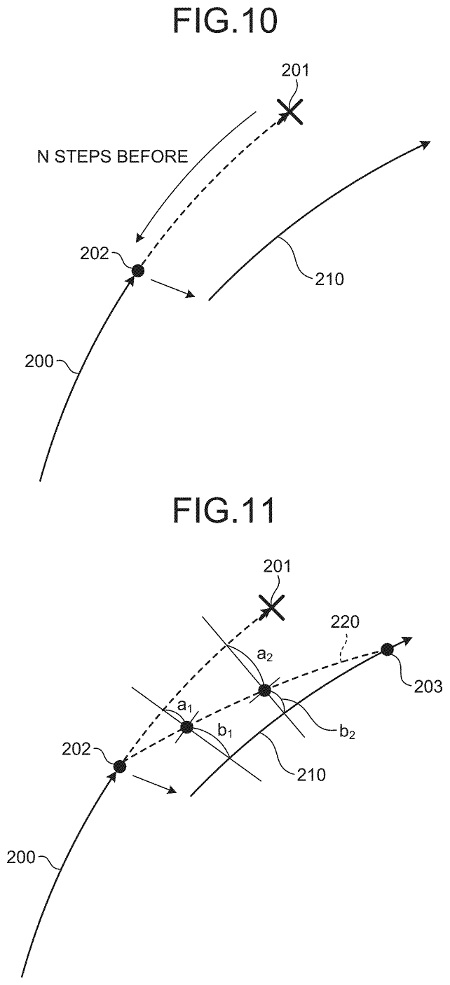

The smoothing processing at step S103 will be explained by using FIG. 10 and FIG. 11. In this example, it is assumed, for explanation, that a vehicle in car races or the like in virtual space is the controlled object 3, and the log information is a traveling path of the vehicle. FIG. 10 is a diagram for explaining necessity of the smoothing processing.

In FIG. 10, a traveling path 200 indicates a traveling path before performing correction of action at step S16 in FIG. 6. At a current position 202, determination at step S15 in FIG. 6 is performed, and it is assumed to be determined that an interference with the other object occurs at the position 201 if it travels along the traveling path 200. A traveling path 210 is supposed to be a traveling path that has been narrowed down at step S102 in FIG. 7 according to this estimation of occurrence of the interference. In the example in FIG. 10, the traveling path 200 and the traveling path 210 are not connected at specific connecting points. Therefore, if the traveling path is switched from the traveling path 200 to the traveling path 210, jumping of the vehicle occurs, and it is not preferable.

For example, if this is applied to the arm robot 60 described above, an angle is to be changed abruptly at the joint portion between the proximal portion 61 and the arm portion 62, and an excessively heavy load is to be applied to the actuator to drive the joint portion.

Therefore, in the first embodiment, at step S103 in FIG. 7, the smoothing processing is performed with respect to the current action and the action subjected to correction, so as continuously transition from the current action to the action subjected to correction.

FIG. 11 is a diagram for explaining the smoothing processing applicable to the first embodiment. In FIG. 11, a case in which transition from the traveling path 200 to the traveling path 210 is started at the position 202, and the transition to the traveling path 210 is completed after traveling for predetermined time (for example, 1 second) from the position 202 is considered. In this case, the smoothing processing is performed by performing linear interpolation between the traveling path 200 and the traveling path 210 from the position 202 of the transition start point to the position 203 of the transition completion point.

More specifically, the correcting unit 103 shifts an extension of the traveling path 200 (indicated by a dotted line connecting the position 202 and the position 201 in FIG. 11) and a line connecting with the traveling path 210 in the shortest distance from the position 202 to the position 203 at each step according to the traveling speed of the vehicle. The correcting unit 103 takes internally dividing points of these lines, to change ratios at which the lines are divided by the internally dividing points into a line from the position 202 to the position 203.

For example, a+b=1 where a value a is a distance from the extension of the traveling path 200 to an internally dividing point, and a value b is a distance from the internally dividing point to the traveling path 210. In this case, a=0 and b=1 at the position 202, and a=1 and b=0 at the position 203. The correcting unit 103 increases and decreases the values a and b for the line at each step at an intermediate point between the position 202 and the position 203 setting as a₁<a₂, b₁>b₂ where a₁+b₁=1, a₂+b₂=1 from the side closer to the position 202. The correcting unit 103 connects the position 202 and the position 203 through the internally dividing points, the positions of which are thus changed at each step. Thus, a traveling path 220 in which the traveling paths 200 and 210 are continuously connected at the positions 202 and 203 is generated, and smoothing by a linear interpolation is performed.

The correcting unit 103 thus corrects an action based on the log information for each step, and sends control information indicating the corrected action (traveling path 220) to the action control unit 11. The action control unit 11 controls an action of the controlled object 3 according to the received control information. Moreover, for example, the correcting unit 103 sends the log information corresponding to the traveling path 210 at the position 203 to the action control unit 11. The action control unit 11 controls an action of the controlled object 3 according to the log information at the position 203 and later.

By thus performing the smoothing, transition from the current action to the action subjected to correction can be smoothly performed. This enables to suppress unnatural action switch in virtual space, or an excessive load on an actuator in a robot or the like.

The smoothing processing at the time of transition from a current action to an action subjected to correction is not limited to the linear interpolation, as long as transition can be performed in a continuous manner. For example, the interpolation processing may be performed by using a curve, such as a quadratic curve.

The read-ahead processing according to the first embodiment will be explained. For example, in the example in FIG. 11 described above, when the action control unit 11 controls, after switching to the traveling path 210, an action of the controlled object 3 according to the log information corresponding to the traveling path 210, an interference to the controlled object 3 can occur at a position further ahead. The action correcting unit 10a reads ahead a state, considering the interference in such a case.

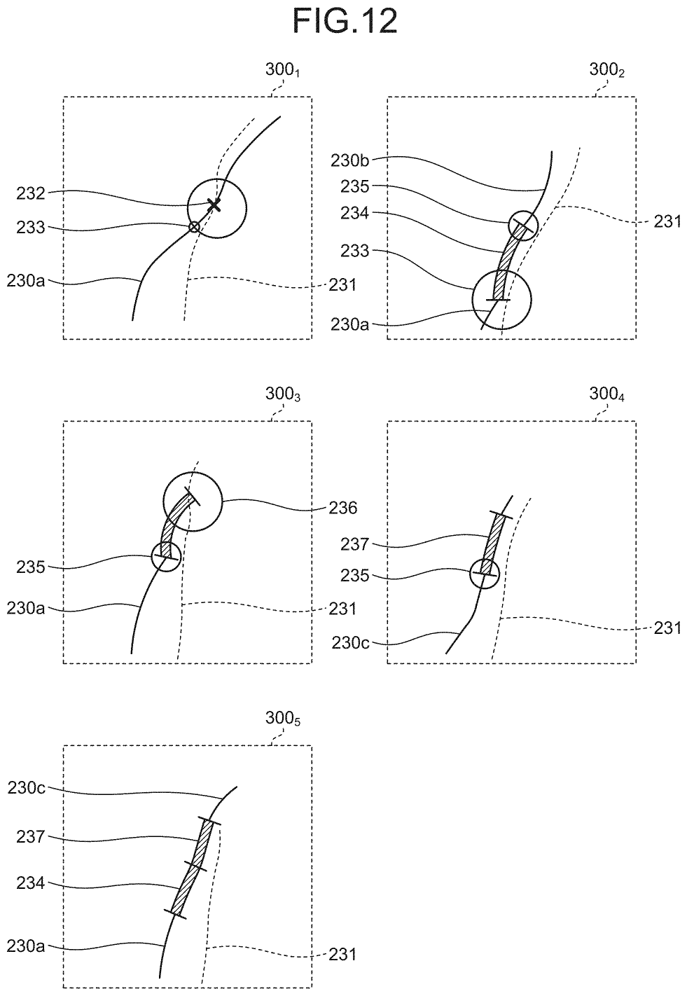

FIG. 12 is a diagram for explaining the read-ahead processing applicable to the first embodiment. The read-ahead processing will be explained, using this FIG. 12, the flowchart in FIG. 6 described above, and the like. For explanation, herein, a vehicle in a car race game or the like is assumed as the controlled object 3, and a traveling path of the vehicle is assumed as the log information, similarly to FIG. 10 and FIG. 11 described above. Moreover, in FIG. 12, sections 300₁, 300₂, 300₃, 300₄, 300₅, and 300₆ indicate changes in a state as time elapses.

In the section 300₁, the action of the controlled object 3 is controlled according to the traveling path 230 based on first log information. It is assumed that by the cost estimating unit 100 and the determining unit 101, the read-ahead is performed up to a predetermined time ahead at a position 233 on a traveling path 230a, and that it has been estimated for the position 233, that there is a possibility of occurrence of interference between itself and another object (the other controlled object 3), the action of which is controlled according to a traveling path 231 based on second log information at a future position 232 (step S14, step S15 in FIG. 6).

In the action correcting unit 10a, the retrieving unit 102 retrieves a state similar to a state at the position 233 from the log information recorded in the log recording unit 2b (step S101 in FIG. 7). As a result, as illustrated in the section 300₂ in an enlarged manner, the interference at the position 232 can be avoided by transitioning to a traveling path 230b based on third log information. Therefore, a range 234 on the traveling path 230b starting from the position 233 is connected to the position 233. At this time, the connection is performed by the smoothing processing explained using FIG. 11.

When the action correction is thus performed by step S16 in FIG. 6, action control of the controlled object 3 is performed according to the action correction result at step S17, and the processing is returned to step S10. In this case, because it is the corrected action, the processing is shifted to step S13.

At step S13, estimation for the traveling path 230b is performed by the state estimating unit 104, and based on the estimation result, the cost estimating unit 100 and the determining unit 101 performs the read-ahead up to a predetermined time ahead at a position 235 on the traveling path 230b as indicated in the section 300₃, and it is estimated that there is a possibility of occurrence of interference again at a position 235 of the traveling path 230b (step S14, step S15 in FIG. 6).

In the action correcting unit 10a, the retrieving unit 102 retrieves a state similar to a state at the position 235 that is a position going back for predetermined time from a position 236 from the log information recorded in the log recording unit 2b (step S101 in FIG. 7). As a result, as illustrated in the section 300₄, the interference at the position 236 can be avoided by transitioning to a traveling path 230c based on fourth log information. Therefore, a range 237 on the traveling path 230c starting from the position 235 is connected to the position 235. At this time, the connection is performed by the smoothing processing explained using FIG. 11.

The section 300s indicates a state in which the range 234 on the traveling path 230b and the range 237 on the traveling path 30c are thus connected to the traveling path 230a.

When it is determined at one position whether there is a possibility of occurrence of an interference, by reading ahead up to a future position, a limit (for example, reading ahead up to 5 seconds ahead) is set to a range to be read ahead. When a possibility of occurrence of an interference within this limited range is low with a traveling path based on the current log information, this traveling path is used. Moreover, the read-ahead processing up to predetermined time ahead described above is performed, for example, for each step. By performing the read-ahead processing at each step, it becomes possible to respond to a current situation immediately.

As described, by recursively performing the action correction according to an interference estimated based on a cost, it becomes possible to estimate, for example, an action to avoid the interference up to future step for a certain length. Thus, the action of the controlled object 3 can be controlled more stably.

### Second Embodiment

Next, a second embodiment of the present disclosure will be explained. The second embodiment is an example in which action correction is performed by using an optimal action estimator that has trained with past log information. The control processing of the controlled object 3 explained in the first embodiment by using FIG. 6 can be applied to the second embodiment similarly except step S16 and, therefore, explanation is omitted herein.

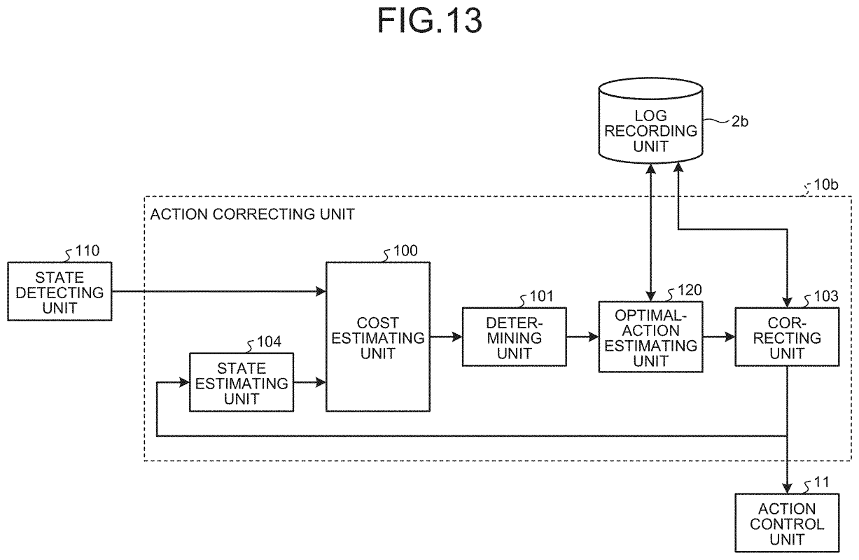

FIG. 13 is an example of a functional block diagram for explaining a function of an action correcting unit 10b according to the second embodiment. The action correcting unit 10b illustrated in FIG. 13 includes an optimal-action estimating unit 120 in place of the retrieving unit 102 of the action correcting unit 10a illustrated in FIG. 5 according to the first embodiment.

The optimal-action estimating unit 120 includes an optimal action estimator that has trained to estimate an optimal action Aₜ in advance from an input state Sₜ, based on past log information recorded in the log recording unit 2b. The optimal action estimator is a parameter of a function G to implement Aₜ=G(Sₜ) trained from the past log information.

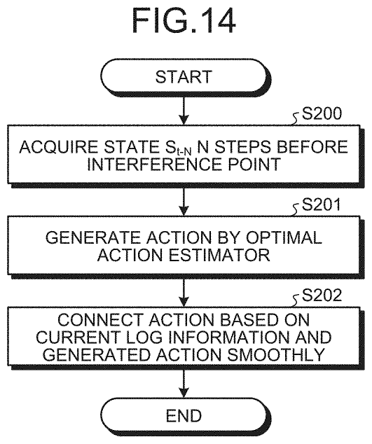

FIG. 14 is an example of a flowchart illustrating action correction processing according to the second embodiment. The processing according to the flowchart in FIG. 14 corresponds to the processing at step S16 in the flowchart in FIG. 6 described above.

At step S200, the action correcting unit 10b acquires, by the retrieving unit 102, the state S_{t-N}(N is a positive integer) of N steps before a time at which the determining unit 101 determines that a possibility of an interference at step S15 in FIG. 6, based on the log information recorded in the log recording unit 2.

At following step S201, the action correcting unit 10b acquires an optimal action Aₜ₊₁ based on the state S_{t-N} acquired at step S200, by the optimal action estimator. Thereafter, the optimal-action estimating unit 120 generates an action based on a new state Sₜ₊₁ derived from the optimal action Aₜ₊₁ output from the optimal action estimator for each step. Thus, chronological information corresponding to the log information is generated.

The optical-action estimating unit 120 compares a generated action and an action based on the log information that has been used before performing the action correction by step S16 in FIG. 6. The optimal-action estimating unit 120 determines whether an action based on the generated new state Sₜ₊₁ and the action based on the log information have come close enough to each other to be smoothly connectable based on a result of the comparison. The optimal-action estimating unit 120 shifts the processing to step S202 at the point of time when it is determined that the those two have come close to each other.

At step S202, the correcting unit 103 performs the smoothing processing to connect the action based on the current log information and the action generated at step S201 smoothly. Because the smoothing processing is similar to the processing explained by using FIG. 10 and FIG. 11 in the first embodiment, explanation thereof is omitted herein.

A configuration method of the optimal-action estimator described above will be explained. As a method of generating the optimal action estimator according to the second embodiment, that is, the parameter of the function G to implement Aₜ=G(Sₜ), a method called behavior cloning disclosed in Non-Patent Literature 1 can be adopted. The behavior cloning is a method in which a pair of optimal action Aₜ with respect to the state Sₜ are prepared in a large quantity as training samples, and these training samples are trained by a neural network.

When a large quantity of training samples cannot be obtained in advance, reinforcement learning disclosed in Patent Literature 2 can be used. In the reinforcement learning, for example, a robot autonomously learns the function G (policy function) in Aₜ=G(Sₜ) through trial and error actions in an environment based on a reward obtained from an environment resulted from a right action.

According to the second embodiment, correction of action is performed by using the optimal-action estimator trained from past log information, even if a large amount of log information is not stored in the log storage unit 2b, an appropriate control can be achieved.

### Third Embodiment

Next, a third embodiment will be explained. The third embodiment is an example of performing correction of action based on a user operation. The control processing of the controlled object 3 explained in the first embodiment by using FIG. 6 can be applied similarly to the third embodiment also, except the processing at step S16 and, therefore, explanation thereof is omitted herein.

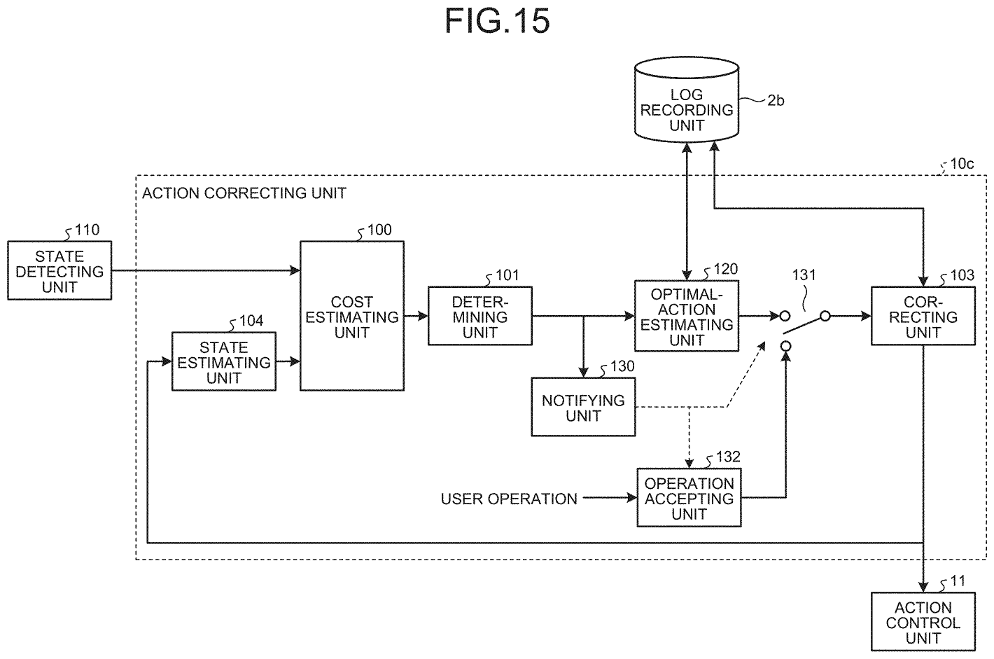

FIG. 15 is an example of a functional block diagram for explaining a function of an action correcting unit 10c according to a third embodiment that corresponds to the action correcting unit 10 in FIG. 2. In the action correcting unit 10c illustrated in FIG. 15, a notifying unit 130, a switch portion 131, and an operation accepting unit 132 are provided, additionally to the action correcting unit 10b according to the second embodiment illustrated in FIG. 13.

When the determining unit 101 determines that a cost calculated by the cost estimating unit 100 is equal to or larger than a predetermined value, the notifying unit 130 notifies of the fact, and performs notification to a user, for example, by a display on the display 1020 or the like. The switch portion 131 switches between an output of the optimal-action estimating unit 120 and an output of the operation accepting unit 132 to determine which to provide to the correcting unit 103, in accordance with a control by the notifying unit 130. The switch portion 131 is controlled to provide an output of the optimal-action estimating unit 120 by default.

The operation accepting unit 132 causes the display 1020 to display a screen of a user interface to perform correction of action by a user operation when it is notified that a calculated cost is equal to or higher than the predetermined value by the notifying unit 130. Besides, the operation accepting unit 132 accepts a user operation input for action control with respect to the input device 1030. The input device 1030 is preferable to be one according to a type of the controlled object 3. For example, it is considered that when the controlled object 3 is a robot, a joystick is used as the input device 1030, and when the controlled object 3 is a vehicle for a race game, a gamepad is used for the input device 1030, or the like.

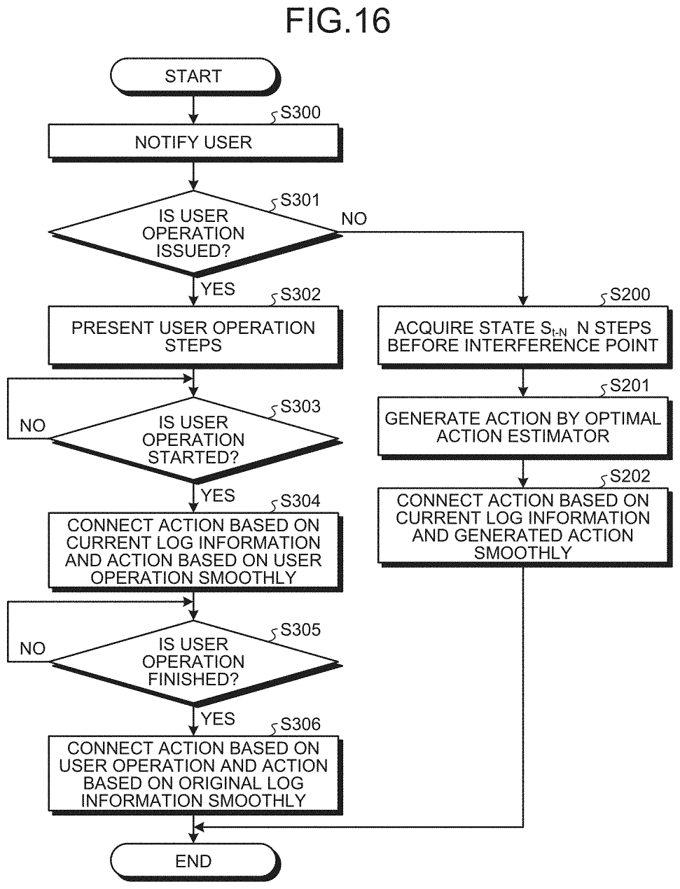

FIG. 16 is an example of a flowchart illustrating action correction processing according to the third embodiment. The processing according to the flowchart in FIG. 16 corresponds to the processing at step S16 in the flowchart in FIG. 6 described above.

At step S15 in FIG. 6, the action correcting unit 10c shifts the processing to step S300 in FIG. 16 when the determining unit 101 determines that there is a possibility of interference caused by an action of the controlled object 3 to another object within predetermined steps from a current point based on a calculated cost. At step S300, the action correcting unit 10c notifies, by the notifying unit 130, a user of the possibility of interference within predetermined steps, for example, by a display on the display 1020.

At following step S301, the notifying unit 130 determines whether an action control by a user operation has been issued in response to the notification at step S300. When it is determined as issued (step S301: “YES”), the notifying unit 130 shifts the processing to step S302. For example, the notifying unit 130 performs the notification display described above with respect to the display 1020, and displays a message to prompt to input whether to perform an action control by a user operation. The notifying unit 130 determines, when an input indicating an intension to perform the action control by a user operation is made in response to the message, that the action control by a user operation has been issued.

At step S302, the operation accepting unit 132 presents a user operation steps to correct the action of the controlled object 3 by a user operation. For example, the operation accepting unit 132 displays a screen to perform a user operation on the display 1020, and starts accepting a user operation with respect to the input device 1030. Moreover, at step S302, the notifying unit 130 controls the switch portion 131 to provide an output of the operation accepting unit 132 to the correcting unit 103.

At following step S303, the operation accepting unit 132 determines whether a user operation to perform correction of an action has been started. When it is determined that it has not been started (step S303: “NO”), the processing is returned to step S303. On the other hand, when it is determined that it has started (step S303: “YES”), the processing is shifted to step S304.

At step S304, the correcting unit 103 corrects the action of the controlled object 3 in accordance with a control signal output according to the user operation from the operation accepting unit 132. At this time, the correcting unit 103 performs the smoothing processing to connect the action based on the current log information and the action in accordance with the control signal output from the operation accepting unit 132 smoothly. The smoothing processing is similar to the processing explained by using FIG. 10 and FIG. 11 in the first embodiment and, therefore, explanation thereof is omitted herein.

At following step S305, the operation accepting unit 132 determines whether the user operation to correct the action has been finished. When it is determined that it has not been finished (step S305: “NO”), the processing is return to step S305. On the other hand, when it is determined that it has been finished (step S305: “YES”), the processing is shifted to step S306.

At step S306, the correcting unit performs the smoothing processing with respect to an end position of the action correction by a user operation to smoothly connect the operation based on the log information that has been used before the user operation is issued at step S301. The smoothing processing is similar to the processing explained by using FIG. 10 and FIG. 11 in the first embodiment and, therefore, explanation thereof is omitted herein.

At step S301 described above, the notifying unit 130 shifts the processing to step S200 to step S202 when it is determined that the action control by a user operation is not issued in response to the notification at step S300 (step S301: “NO”), and performs the action correction by using the optimal action estimator trained from past log information explained in the second embodiment.

In the third embodiment, data of an action correction in accordance with a user operation can be recorded, for example, in the log recording unit 2b as training data. By additionally training the optimal action estimator in the estimating unit 120, using this training data, improvement of the optimal action estimator is possible. Moreover, by adding this training data to the log recording unit 2b according to the first embodiment as log information, instruction information in accordance with the user operation can be used for correction of an action of the controlled object 3 based on the log information, for example, and improvement in performance of avoiding an interference with another object can be expected.

### Other Embodiments

Application of Present Disclosure to Computer Game

Computer games in which a game situation can be retrieve based on log information have been known. In such a computer game, for example, a game situation operated by a user in an environment in the game is recorded as log information. By replaying the game based on the recorded log information at a later time, the game situation can be retrieved in an environment in the game in which the log information has been recorded. Moreover, for example, in a car racing game or the like, log information imitating a racing style of one driver can be generated in advance, and a non-player character (NPC) in the game can be configured also.

By applying the present disclosure to such a computer game, for example, many combinations of new play data can be reconfigured based on a limited number of log information recorded in past.

For example, plural pieces of log information of plural players recorded in past are extracted. The respective controlled objects 3 corresponding to the respective pieces of the extracted log information are caused to perform an action based on the corresponding log information. When it is determined that there is a possibility of interference by the respective other controlled objects 3 to itself, an action of each of the controlled object 3 is corrected, for example, as explained in the first embodiment and the second embodiment. According to this, a new action by an NPC can be implemented more naturally.

In this case, log information to control an action of the controlled object 3 can be generated, for example, based on information about an actual professional player. Thus, a game situation as if plural professional players are actually competing can be configured. Furthermore, by mixing an action in accordance with a user operation, a situation as if a user is competing with a professional player can be created.

Furthermore, according to the present disclosure, because new play data can be reconfigured as described above, it is possible to avoid a user that is skilled in operating and have full knowledge of characteristics of the game from getting bored of the game itself as the user completely become aware of characters of NPCs.

Application of Present Disclosure to Control of Drone

In a field of entertainment, controlling plural drones at positions relating to each other are controlled as a group. For example, flight trajectories of the respective drone are determined in advance to be respectively recorded as log information, and flight of the respective drones can be controlled based on the respective recorded log information. In such a case, for example, one drone out of the plural drones included in a group can collide with the other drones by any accident.

By applying the present disclosure to an action control of the drone group, it is possible to cope with such an accident. Log information to perform action control of a single drone as the controlled object 3 is generated and recorded in advance. The action control of each drone included in the drone group is performed based on this recorded log information.

When another drone comes close to a focused drone out of the plural drones included in the drone group, an interference by the other drone is estimated, and an action based on the log information of the focused drone is corrected to avoid the interference as explained in the first embodiment and the second embodiment. Thus, it is possible to avoid the focused drone from coming into collision with the other drone that has come close thereto by an accident or the like.

The present disclosure can take following configurations also.

(1) A control device comprising:

a control unit that controls an action of a controlled object based on first chronological information;

an estimating unit that estimates a cost produced by achievement of a purpose of the controlled object; and

a correcting unit that corrects an action of the controlled object based on the first chronological information, according to the cost estimated by the estimating unit.

(2) The control device according to (1), wherein

the correcting unit corrects the action based on the first chronological information to an action that continues from an action based on second chronological information different from the first chronological information.

(3) The control device according to (2), further comprising

a retrieving unit that retrieves, according to the cost estimated by the estimating unit, a similar state that is similar to a state corresponding to the estimation from at least one piece of chronological information, wherein

the second chronological information is chronological information that is obtained by retrieving the similar state from the at least one piece of the chronological information by the retrieving unit.

(4) The control device according to (3), wherein

the retrieving unit retrieves the similar state similar to an environment that includes a state corresponding to the estimation.

(5) The control device according to (2), wherein

the second chronological information is chronological information according to an action estimated as optimal by training performed with the first chronological information as input information.

(6) The control device according to (2), wherein

the second chronological information is chronological information according to an action estimated as optimal, by training by autonomous trial and error actions by the controlled object.

(7) The control device according to (2), wherein

the correcting unit corrects an action based on the first chronological information based on a user operation to control an action of the controlled object.

(8) The control device according to (7), wherein

the correcting unit adds third chronological information according to the action corrected based on the user operation to the first chronological information.

(9) The control device according to any one of (1) to (8), wherein

the correcting unit further performs correction according to the cost estimated by the estimating unit with respect to an action of the controlled object that is controlled by the control unit based on the corrected first chronological information.

(10) The control device according to any one of (1) to (9), wherein

the estimating unit estimates the cost according to a possibility that the controlled object interferes another object.

(11) The control device according to any one of (1) to (10), wherein

the estimating unit estimates the cost based on a detection result by a detecting unit that detects a peripheral state of the controlled object.

(12) The control device according to any one of (2) to (11), wherein

the control unit controls an action of the controlled object based on the first chronological information in a second environment different from a first environment corresponding to the first chronological information.

(13) The control device according to (12), wherein

the control unit controls an action of the controlled object based on the first chronological information generated in the first environment.

(14) The control device according to (12) or (13), wherein

the first chronological information is generated according to fixed patterns in advance.

(15) The control device according to any one of (12) to (14), wherein the controlled object is a robot for factory automation.
(16) The control device according to (12), wherein

the control unit controls an action of the controlled object in the second environment in which a plurality of objects act including the controlled object simultaneously act, based on the first chronological information generated in the first environment in which the controlled object acts by itself.

(17) The control device according to (16), wherein

the controlled object is an unmanned aircraft that can be externally flight-controlled.

(18) The control device according to (2), wherein

the control unit controls an action of the controlled object in virtual space based on the first chronological information.

(19) The control device according to (18), wherein

the correcting unit corrects an action based on the first chronological information of the controlled object according to the cost estimated based on a user operation to control an action of another controlled object that is different from the controlled object.

(20) The control device according to (19), wherein

the estimating unit estimates the cost according to a speed of at least one of the controlled object and the other controlled object.

(21) A control method comprising:

a control step of controlling an action of a controlled object based on first chronological information;

an estimating step of estimating a cost produced by achievement of a purpose of the controlled object; and

a correcting step of correcting an action of the controlled object based on the first chronological information, according to the cost estimated by the estimating unit.

### REFERENCE SIGNS LIST

1a, 1b CONTROL DEVICE
2a, 2b LOG RECORDING UNIT
3 CONTROLLED OBJECT
4 ENVIRONMENT
5 SENSOR
10a, 10b, 10c ACTION CORRECTING UNIT
11 ACTION CONTROL UNIT
20, 20₁, 20₂, 20₃, 20n LOG INFORMATION
100 COST ESTIMATING UNIT
101 DETERMINING UNIT
102 RETRIEVING UNIT
103 CORRECTING UNIT
104 STATE ESTIMATING UNIT
110 STATE DETECTING UNIT
120 OPTIMAL-ACTION ESTIMATING UNIT
130 NOTIFYING UNIT
131 SWITCH PORTION
132 OPERATION ACCEPTING UNIT

1. A control device comprising:
a control unit that controls an action of a controlled object based on first chronological information;
an estimating unit that estimates a cost produced by achievement of a purpose of the controlled object; and
a correcting unit that corrects an action of the controlled object based on the first chronological information, according to the cost estimated by the estimating unit.

2. The control device according to claim 1, wherein
the correcting unit corrects the action based on the first chronological information to an action that continues from an action based on second chronological information different from the first chronological information.

3. The control device according to claim 2, further comprising
a retrieving unit that retrieves, according to the cost estimated by the estimating unit, a similar state that is similar to a state corresponding to the estimation from at least one piece of chronological information, wherein
the second chronological information is chronological information that is obtained by retrieving the similar state from the at least one piece of the chronological information by the retrieving unit.

4. The control device according to claim 3, wherein
the retrieving unit retrieves the similar state similar to an environment that includes a state corresponding to the estimation.

5. The control device according to claim 2, wherein
the second chronological information is chronological information according to an action estimated as optimal by training performed with the first chronological information as input information.

6. The control device according to claim 2, wherein
the second chronological information is chronological information according to an action estimated as optimal, by training by autonomous trial and error actions by the controlled object.

7. The control device according to claim 2, wherein
the correcting unit corrects an action based on the first chronological information based on a user operation to control an action of the controlled object.

8. The control device according to claim 7, wherein
the correcting unit adds third chronological information according to the action corrected based on the user operation to the first chronological information.

9. The control device according to claim 1, wherein
the correcting unit further performs correction according to the cost estimated by the estimating unit with respect to an action of the controlled object that is controlled by the control unit based on the corrected first chronological information.

10. The control device according to claim 1, wherein
the estimating unit estimates the cost according to a possibility that the controlled object interferes another object.

11. The control device according to claim 1, wherein
the estimating unit estimates the cost based on a detection result by a detecting unit that detects a peripheral state of the controlled object.

12. The control device according to claim 2, wherein
the control unit controls an action of the controlled object based on the first chronological information in a second environment different from a first environment corresponding to the first chronological information.

13. The control device according to claim 12, wherein
the control unit controls an action of the controlled object based on the first chronological information generated in the first environment.

14. The control device according to claim 12, wherein
the first chronological information is generated according to fixed patterns in advance.

15. The control device according to claim 12, wherein
the control unit controls an action of the controlled object in the second environment in which a plurality of objects act including the controlled object simultaneously act, based on the first chronological information generated in the first environment in which the controlled object acts by itself.

16. The control device according to claim 2, wherein
the control unit controls an action of the controlled object in virtual space based on the first chronological information.

17. The control device according to claim 16, wherein
the correcting unit corrects an action based on the first chronological information of the controlled object according to the cost estimated based on a user operation to control an action of another controlled object that is different from the controlled object.

18. The control device according to claim 17, wherein
the estimating unit estimates the cost according to a speed of at least one of the controlled object and the other controlled object.

19. A control method comprising:
a control step of controlling an action of a controlled object based on first chronological information;
an estimating step of estimating a cost produced by achievement of a purpose of the controlled object; and
a correcting step of correcting an action of the controlled object based on the first chronological information, according to the cost estimated by the estimating unit.
